(19) United States
(12) Patent Application Publication
(10) Pub. No.: US 2023/0110079 A1
(43) Pub. Date: Apr. 13, 2023

(54) FAN-OUT PACKAGE STRUCTURE AND MANUFACTURING METHOD THEREOF

(71) Applicant: POWERTECH TECHNOLOGY INC., Hsinchu (TW)

(72) Inventors: Pei-chun Tsai, Hsinchu (TW); Hung-hsin Hsu, Hsinchu (TW); Ching-wei Liao, Hsinchu (TW); Shang-yu Chang Chien, Hsinchu (TW)

(73) Assignee: POWERTECH TECHNOLOGY INC., Hsinchu (TW)

(21) Appl. No.: 17/821,168

(22) Filed: Aug. 20, 2022

(30) Foreign Application Priority Data
Oct. 8, 2021 (TW) 110137625

(51) Int. Cl. H01L 25/16; H01L 23/00; H01L 21/56; H01L 23/498

(52) U.S. Cl. CPC H01L 25/162; H01L 24/32; H01L 24/16; H01L 24/73; H01L 24/96; H01L 24/97; H01L 24/17; H01L 21/561; H01L 21/563; H01L 21/565; H01L 21/568; H01L 23/49833; H01L 23/49838; H01L 23/49816; H01L 23/49822; H01L 2924/182; H01L 2924/3511; H01L 2924/3512; H01L 2224/95001; H01L 2224/32225; H01L 2224/73204; H01L 2224/73253; H01L 2224/1601; H01L 2224/16227; H01L 2224/16238; H01L 2224/1703; H01L 2924/381

(57) ABSTRACT

A fan-out package structure and a manufacturing method thereof are provided. The fan-out package structure includes an upper redistribution layer, a die, a passive element, and an active element. The upper redistribution layer includes a first surface and a second surface opposite to the first surface. The die is disposed on the first surface of the upper redistribution layer and is electrically connected to the upper redistribution layer. The passive element is disposed on the second surface of the upper redistribution layer and is electrically connected to the upper redistribution layer. The active element is disposed on the second surface of the upper redistribution layer and is electrically connected to the upper redistribution layer. The active element is laterally adjacent to the passive element, and the die is electrically connected to the active element and the passive element through the upper redistribution layer.

### CROSS REFERENCE TO RELATED APPLICATIONS

This application claims priority to Taiwan Application Serial No. 110137625, filed Oct. 8, 2021, the disclosure of which is incorporated herein by reference.

### FIELD OF DISCLOSURE

The present disclosure relates to the field of semiconductors, in particular to a fan-out package structure and a manufacturing method thereof.

### BACKGROUND

With the rapid development of semiconductor technologies, a demand for thinner and lighter packaging structures has gradually increased. At present, there are two main development directions for advanced packaging. One is to reduce a package area to make it close to a chip size, and the other is to integrate multiple chips in one package to increase a degree of integration within the package. Therefore, for a multi-chip package structure, how to achieve electrical connection between multiple components without increasing a package width is a focus of current industry research and a technical problem that needs to be resolved.

Accordingly, the present disclosure provides a fan-out package structure and a manufacturing method thereof to solve the above technical problems.

### SUMMARY OF DISCLOSURE

The present disclosure provides a fan-out package structure and a manufacturing method thereof to realize electrical connection between multiple components without increasing a package size.

In one aspect, the present disclosure provides a fan-out package structure, including: an upper redistribution layer, a die, a passive element, and an active element. The upper redistribution layer includes a first surface and a second surface opposite to the first surface. The die is disposed on the first surface of the upper redistribution layer and is electrically connected to the upper redistribution layer. The passive element is disposed on the second surface of the upper redistribution layer and is electrically connected to the upper redistribution layer. The active element is disposed on the second surface of the upper redistribution layer and is electrically connected to the upper redistribution layer. The active element is laterally adjacent to the passive element, and the die is electrically connected to the active element and the passive element through the upper redistribution layer.

In some embodiments, an orthographic projection of the active element on the upper redistribution layer partially overlaps with an orthographic projection of the die on the upper redistribution layer, and an orthographic projection of the passive element on the upper redistribution layer overlaps with the orthographic projection of the die on the upper redistribution layer.

In some embodiments, the upper redistribution layer includes: a first connection pad, a plurality of second connection pads, a third connection pad, a first wire, and a second wire. The first connection pad is formed on the first surface and is configured to connect with the die. The plurality of second connection pads are formed on the second surface and are configured to connect with the passive element. The third connection pad is formed on the second surface and is configured to connect with the active element. The first wire is formed in the upper redistribution layer and is configured to vertically connect the first connection pad and one of the plurality of second connection pads. The second wire is formed in the upper redistribution layer and is configured to laterally connect one of the second connection pads and the third connection pad.

In some embodiments, the fan-out package structure further includes a first insulating layer and a second insulating layer. The first insulating layer is disposed on the second surface of the upper redistribution layer and is configured to encapsulate the passive element and the active element. The second insulating layer is disposed on the die and the upper redistribution layer and is configured to encapsulate the die. The second insulating layer includes an opening, and a surface of the die is exposed to an outside through the opening.

In some embodiments, the fan-out package structure further includes a lower redistribution layer and a patterned adhesive layer disposed on the lower redistribution layer. One surface of the passive element and one surface of the active element are adhered to the lower redistribution layer through the patterned adhesive layer, and one other surface of the passive element and one other surface of the active element are electrically connected to the upper redistribution layer.

In some embodiments, the fan-out package structure further includes a first conductive pillar, a second conductive pillar, and a third conductive pillar. The first conductive pillar is configured to connect the upper redistribution layer and the lower redistribution layer. The second conductive pillar is configured to connect the passive element and the upper redistribution layer. The third conductive pillar is configured to connect the active element and the upper redistribution layer. A pitch of the first conductive pillar is greater than or equal to a pitch of the third conductive pillar, and the pitch of the third conductive pillar is greater than or equal to a pitch of the second conductive pillar.

In some embodiments, the fan-out package structure further includes a underfill layer disposed between the upper redistribution layer and the die.

In some embodiments, the fan-out package structure further includes a protective ring or a protective cover disposed on the first surface of the upper redistribution layer and surrounding the die.

In another one aspect, the present disclosure also provides manufacturing method of a fan-out package structure, including steps of: providing a lower redistribution layer; forming a passive element and an active element on the lower redistribution layer; forming an upper redistribution layer on the passive element and the active element, where the passive element and the active element are electrically connected to the upper redistribution layer, and the passive element is laterally adjacent to the active element; and forming a die on the upper redistribution layer, where the die is electrically connected to the passive element and the active element through the upper redistribution layer.

In some embodiments, in the step of forming the die on the upper redistribution layer, the die is disposed to partially overlap with the active element and overlap with the passive element.

In the fan-out package structure and the manufacturing method thereof of the present disclosure, the passive element may be a bridge chip or a functional chip integrated with a bridge function. The passive element can realize a signal transmission between the die and the active element, making an arrangement of the die and the active element more flexible, and the two are not limited to only a specific arrangement. For example, through the passive element, the die and the active element can be arranged at different levels. When viewed from a top view, the die and the active element can be arranged to overlap each other. Therefore, in the fan-out package structure of the present disclosure, under a condition of meeting a package width, a miniaturized and compactly designed multi-chip three-dimensional package is realized by the passive element. Furthermore, it provides more design flexibility and freedom for applications of the fan-out package structure of the present disclosure in high-end products.

### BRIEF DESCRIPTION OF DRAWINGS

FIG. 1 shows a schematic diagram of a fan-out package structure of a first embodiment of the present disclosure.

FIG. 2A to FIG. 2L show a series of cross-sectional views to illustrate manufacturing processes of the fan-out package structure of FIG. 1.

FIG. 3 shows a schematic diagram of a fan-out package structure of a second embodiment of the present disclosure.

FIG. 4 shows a schematic diagram of a fan-out package structure of a third embodiment of the present disclosure.

FIG. 5 shows a schematic diagram of a fan-out package structure of a fourth embodiment according to the present disclosure.

FIG. 6 shows a schematic diagram of a fan-out package structure of a fifth embodiment according to the present disclosure.

### DETAILED DESCRIPTION

Exemplary embodiments will now be described more fully with reference to the accompanying drawings. However, the exemplary embodiments can be implemented in various forms, and should not be construed as being limited to the examples set forth herein. On the contrary, providing these embodiments makes the present disclosure more comprehensive and complete, and fully conveys the concept of the exemplary embodiments to those skilled in the art. The drawings are only schematic illustrations of the present disclosure, and are not necessarily drawn to scale. The same reference numerals in the figures denote the same or similar parts, and thus their repeated description will be omitted.

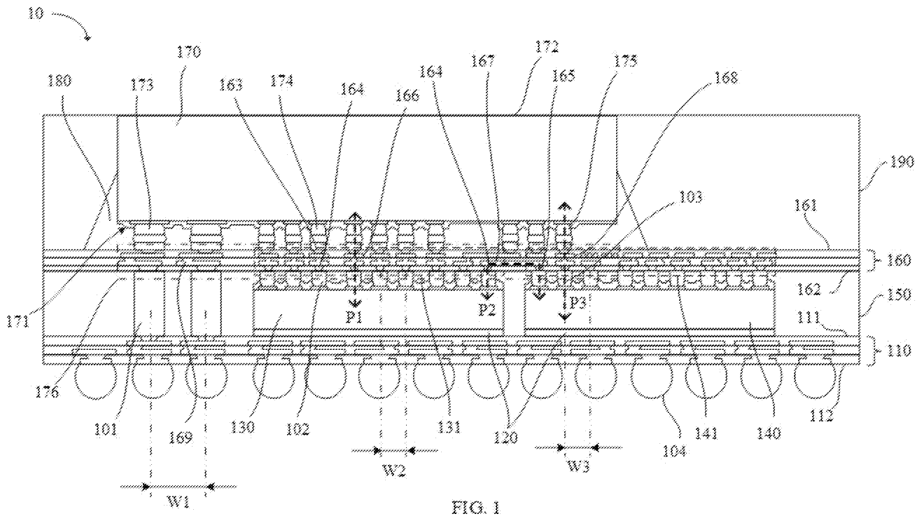

Referring to FIG. 1, which shows a schematic diagram of a fan-out package structure of a first embodiment of the present disclosure. The fan-out package structure 10 includes a lower redistribution layer (RDL) 110, a patterned adhesive layer 120, a passive element 130, an active element 140, a first insulating layer 150, an upper redistribution layer 160, a die 170, an underfill layer 180, and a second insulating layer 190.

As shown in FIG. 1, the lower redistribution layer 110 includes a first connection surface 111 and a second connection surface 112, and a plurality of connection pads are formed on the first connection surface 111 and the second connection surface 112. The first connection surface 111 of the lower redistribution layer 110 is electrically connected to a plurality of first conductive pillars 101 through corresponding connection pads, and the second connection surface 112 of the lower redistribution layer 110 is electrically connected to a plurality of conductive terminals 104 through corresponding connection pads. In this embodiment, a number of the first conductive pillars 101 is two, but it is not limited to this. The first conductive pillar 101 can be made of copper, aluminum, tin, gold, silver, or a combination of the above. Furthermore, the conductive terminal 104 can be formed by using a bumping process, an electroplating process, or other suitable processes. In some embodiments, the conductive terminal 104 is a solder ball formed by a ball implantation process, thereby reducing a manufacturing cost and improving a manufacturing efficiency. It should be understood that, according to design requirements, the conductive terminal 104 may adopt other possible materials and shapes, and is not limited thereto. Alternatively, a bonding force between the conductive terminal 104 and the corresponding connection pad of the lower redistribution layer 110 is enhanced by a welding process and a reflow process.

As shown in FIG. 1, the patterned adhesive layer 120 is vertically disposed on the first connection surface 111 of the lower redistribution layer 110, and the passive element 130 and the active element 140 are vertically disposed on the patterned adhesive layer 120. The passive element 130 and the active element 140 are adhered to the lower redistribution layer 110 through the patterned adhesive layer 120. Specifically, the patterned adhesive layer 120 includes a plurality of adhesive units, and the plurality of adhesive units are arranged on the first connection surface 111 of the lower redistribution layer 110. The passive element 130 is arranged corresponding to one of the glue units, and the active element 140 is arranged corresponding to one other glue unit. The passive element 130 and the active element 140 are adhered to the lower redistribution layer 110 through the patterned adhesive layer 120. Preferably, the patterned adhesive layer 120 can be a die attach film (DAF), and the patterned adhesive layer 120 can effectively enhance a stability of the passive element 130 and the active element 140, thereby preventing the passive element 130 and the active element 140 from shifting or separating during subsequent processes. It should be noted that the passive element 130 and the active element 140 are laterally adjacent to each other, and both are arranged at the same or approximately the same level. In addition, a plurality of connection pads and a plurality of second conductive pillars 102 arranged on the plurality of connection pads are formed on a surface of the passive element 130 away from the patterned adhesive layer 120. Similarly, on a surface of the active element 140 away from the patterned adhesive layer 120, a plurality of connection pads and a plurality of third conductive pillars 103 arranged on the plurality of connection pads are also formed. The second conductive pillar 102 and the third conductive pillar 103 can be made of copper, aluminum, tin, gold, silver, or a combination of the foregoing.

As shown in FIG. 1, the first insulating layer 150 is vertically arranged on the first connection surface 111 of the lower redistribution layer 110, the passive element 130, and the active element 140. The first insulating layer 150 packages the first connection surface 111 of the lower redistribution layer 110 and the components (e.g., the first conductive pillars 101, the passive element 130, and the active element 140) on it, and only corresponding surfaces of the first conductive pillars 101, a corresponding surface of the second conductive pillar 102, and a corresponding surface of the third conductive pillar 103 are exposed for electrical connection with subsequently formed elements.

As shown in FIG. 1, the upper redistribution layer 160 is vertically disposed on a surface of the first insulating layer 150 away from the lower redistribution layer 110. The upper redistribution layer 160 includes a first surface 161 and a second surface 162 opposite to the first surface 161. A plurality of first connection pads 163 are formed on the first surface 161 of the upper redistribution layer 160, and a plurality of second connection pads 164 and a plurality of third connection pads 165 are formed on the second surface 162 of the upper redistribution layer 160. The upper redistribution layer 160 is electrically connected to the second conductive pillars 102 of the passive element 130 through the plurality of second connection pads 164, and the upper redistribution layer 160 is electrically connected to the third conductive pillars 103 of the active element 140 through the plurality of third connection pads 165. Furthermore, the upper redistribution layer 160 also includes a plurality of first wires 166 and at least one second wire 167. The first wires 166 and the second wire 167 are formed inside the upper redistribution layer 160. The first wire 166 is configured to vertically connect one of the first connection pads 163 and one of the second connection pads 164, and the second wire 167 is configured to laterally connect one of the second connection pads 164 and one of the third connection pads 165. In addition, at least one third wire 168 and a pair of fourth wires 169 are arranged inside the upper redistribution layer 160. The third wire 168 is configured to vertically connect one of the first connection pads 163 and one of the third connection pads 165. The fourth wires 169 are electrically connected to the first conductive pillars 101 through the corresponding connection pads. In this embodiment, an electrical connection between the passive element 130 and the active element 140 and the upper redistribution layer 160 is realized through the second conductive pillars 102 and the third conductive pillars 103, which can prevent a bonding interface between low-k materials and the passive element 130 and the active element 140 from cracking due to external stress or internal stress of the process, thereby causing wire breakage and low reliability.

As shown in FIG. 1, the die 170 is vertically disposed on the first surface 161 of the upper redistribution layer 160 and is electrically connected to the upper redistribution layer 160. The die 170 includes an active surface 171 and a back surface 172 opposite to the active surface 171. The active surface 171 of die 170 is provided with a plurality of first bumps 173, a plurality of second bumps 174, and at least one third bump 175. Materials of the first bump 173, the second bump 174, and the third bump 175 may be or include copper, gold, nickel, metal alloys, and the like. The die 170 adopts a flip chip bonding technology to bond the first bumps 173, the second bumps 174, and the third bump 175 to the upper redistribution layer 160 to realize electrical connection between the die 170 and the upper redistribution layer 160. Specifically, the upper redistribution layer 160 is provided with connecting elements protruding from the first surface 161, and these connecting elements are arranged corresponding to the first connection pads 163 on the first surface 161. The connecting elements are also arranged corresponding to the bumps of the die 170, and the connecting elements and the bumps can be correspondingly connected by welding and other techniques. In some embodiments, the connecting elements of the upper redistribution layer 160 can also be omitted to simplify the manufacturing process and improve production efficiency.

As shown in FIG. 1, the first bumps 173 of the die 170 are electrically connected to the lower redistribution layer 110 through the fourth wires 169 and first conductive pillars 101 of the upper redistribution layer 160. A path formed by the first bump 173, the fourth wire 169, and the first conductive pillar 101 serves as a power path of the die 170. In addition, the second bumps 174 of the die 170 are electrically connected to the passive element 130 through the first wires 166 and the second conductive pillars 102 of the redistribution layer 160. A path P1 formed by the second bump 174, the first wire 166, and the second conductive pillar 102 is a main signal transmission path of the die 170. The second conductive pillar 102 of the passive element 130 is electrically connected to the active element 140 through the second wire 167 and the third conductive pillar 103 of the upper redistribution layer 160. A path P2 formed by the second conductive pillar 102, the second wire 167, and the third conductive pillar 103 is a main signal transmission path of the active element 140. In other words, a main signal between the die 170 and the active element 140 is transmitted by the path P1 and the path P2, and the passive element 130 serves as a bridging element between the die 170 and the active element 140. On the other hand, the third bump 175 of the die 170 is electrically connected to the active element 140 through the third wire 168 and the third conductive pillar 103 of upper redistribution layer 160. A path P3 formed by the third bump 175, the third wire 168, and the third conductive pillar 103 serves as a ground or power transmission path of the active element 140. It should be noted that a number of the path P3 is less than a number of the path P1.

As shown in FIG. 1, a pitch of the first bump 173 is less than a pitch W1 of the first conductive pillar 101, a pitch of the second bump 174 is less than a pitch W2 of the second conductive pillar 102, and a pitch of the third bump 175 is less than a pitch W3 of the third conductive pillar 103. There are different pitches for the bumps and the conductive pillars used to connect different components. For example, the pitch W1 of the first conductive pillar 101 is greater than the pitch W3 of the third conductive pillar 103, and the pitch W3 of the third conductive pillar 103 is greater than or equal to the pitch W2 of the second conductive pillar 102. By vertically connecting the die 170, the upper redistribution layer 160, and the lower redistribution layer 110 with the largest size first conductive pillar 101 and first bump 173, an impedance can be effectively reduced, a power path is shortened, and a power drop is reduced, thereby obtaining a good power integrity performance. The intermediate size third bump 175 and third conductive pillar 103 provide good grounding lines for the active element 140. Preferably, the second bump 174, the second conductive pillar 102, and the second connection pad 164 and the first wire 166 of the upper redistribution layer 160 are formed using a fine pitch technology. The use of the fine pitch technology can reduce the size of the corresponding connected chip and increase the function of the chip, so as to accommodate more I/O terminals in a small chip. In some embodiments, the pitch W2 (fine pitch) of the second conductive pillar 102 may range from 45 to 50 micrometers, or less than 40 micrometers.

As shown in FIG. 1, the underfill layer 180 is disposed between the upper redistribution layer 160 and the die 170. Specifically, the underfill layer 180 can be formed in a gap between the active surface 171 of the die 170 and the upper surface 161 of the upper redistribution layer 160, and laterally cover the corresponding connecting elements of the active surface 171 and the upper surface 161 to enhance the bonding force between the die 170 and the upper redistribution layer 160 and enhance the reliability of the bonding. In some embodiments, the underfill layer 180 can be omitted to simplify the manufacturing process and improve the production efficiency.

As shown in FIG. 1, the second insulating layer 190 is vertically arranged on the die 170 and the upper redistribution layer 160, and is configured to encapsulate the die 170. In this embodiment, the second insulating layer 190 includes an opening, and the back surface 172 of the die 170 is exposed to an outside through the opening. With this design, a heat dissipation performance of the die 170 can be effectively improved.

In this embodiment, the die 170 may be a system on a chip (SoC). The passive element 130 may be a bridge chip or a functional chip integrated with a bridge function. The active element 140 may be a memory chip or the like, such as a non-volatile and/or volatile memory. The non-volatile memory can include a read only memory (ROM), a programmable ROM (PROM), an electrically programmable ROM (EPROM), an electrically erasable programmable ROM (EEPROM) and a flash memory. The volatile memory may include a random-access memory (RAM) and the like. In the present disclosure, the passive element 130 is used to realize the signal transmission between the die 170 and the active element 140, which makes the arrangement of the die 170 and the active element 140 more flexible, and is not limited to that the two can only adopt a specific arrangement, such as a traditional packaging structure which arranges all active elements in parallel on the same layer. For example, in this embodiment, through the setting of the passive element 130, the die 170 and the active element 140 can be arrange at different levels, and when viewed from a top view, the die 170 and the active element 140 can be arranged to overlap each other. Specifically, the die 170 and the active element 140 are respectively arranged on opposite sides of the upper redistribution layer 160. In addition, an orthographic projection 141 of the active element 140 on the upper redistribution layer 160 partially overlaps an orthographic projection 176 of the die 170 on the upper redistribution layer 160. In some embodiments, the orthographic projection 141 of the active element 140 on the upper redistribution layer 160 can also be designed to overlap the orthographic projection 176 of the die 170 on the upper redistribution layer 160, that is, the orthographic projection 141 is within a range of the orthographic projection 176. Therefore, in the fan-out package structure 10 of the present disclosure, under a condition of meeting a package width, a miniaturized and compactly designed multi-chip three-dimensional package is realized by the passive element 130. Thus, it provides more design flexibility and freedom for applications of the fan-out package structure 10 of the present disclosure in high-end products. On the other hand, in this embodiment, an orthographic projection 131 of the passive element 130 on the upper redistribution layer 160 overlaps the orthographic projection 176 of the die 170 on the upper redistribution layer 160, that is, the orthographic projection 131 is within a range of the orthographic projection 176. With the overlapping design of the passive element 130 and the die 170, the path P1 for transmitting the main signal can be effectively shortened.

In this embodiment, the large-size first conductive pillar 101, passive element 130, and active element 140 are embedded in the fan-out package structure 10 using an embedded technology to minimize the size of the fan-out package structure 10. Thus, a height requirement for the package is maintained. Advantages of the embedded technology include improved electrical performance, reduced noise, reduced product width, and reduced costs. Furthermore, the present disclosure uses the fine wiring of the upper redistribution layer 160 as the signal transmission path between multiple chips, which can effectively increase a signal transmission speed and reduce a wiring area, thereby ensuring the electrical connection between the multiple chips and achieving the design of high circuit density and fine pitch. On the other hand, in a traditional package structure, in order to avoid a problem of warpage, it is necessary to additionally provide dummy dies in the same layer as the passive element 130 and the first conductive pillar 101. Compared with the traditional packaging structure, the present disclosure can effectively reduce the dummy dies and further reduce a material usage of the first insulating layer 150 by placing the active element 140 in the same layer as the passive element 130 and the first conductive pillars 101. At the same time, it also solves the problem of the fan-out package structure 10 that is prone to warping.

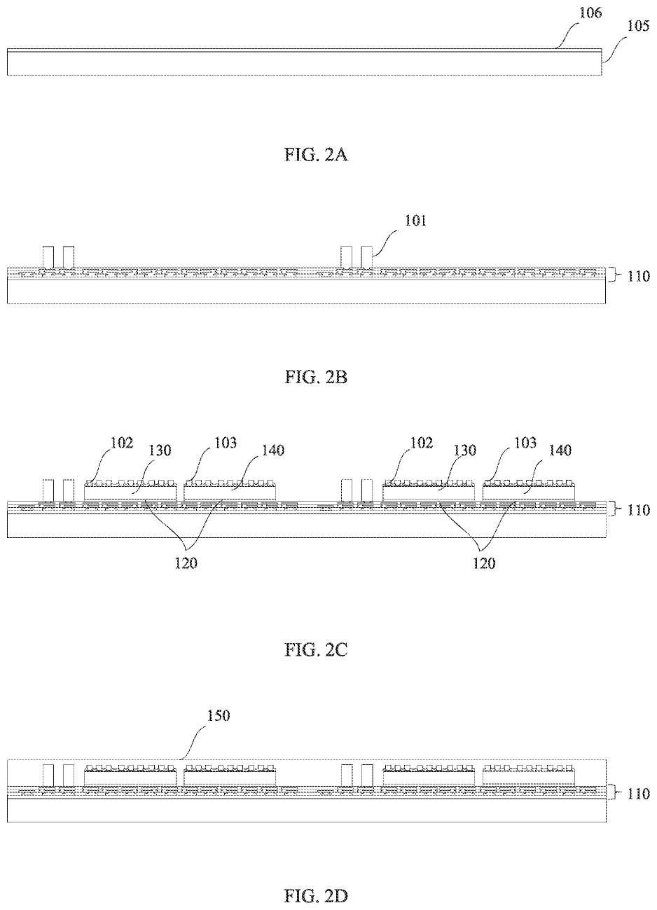

Referring to FIG. 2A to FIG. 2L, which show a series of cross-sectional views to illustrate manufacturing processes of the fan-out package structure of FIG. 1.

As shown in FIG. 2A, a carrier board 105 is provided, and a separation layer 106 is formed vertically on the carrier board 105. The separation layer 106 is configured to separate a subsequently formed film layer from a surface of the carrier board 105. In addition, the separation layer 106 can also provide sufficient bonding force (through adhesion and/or other bonding force) between the carrier board 105 and the subsequently formed film layer, so that the subsequent film layer can be formed successfully.

As shown in FIG. 2B, a lower redistribution layer 110 and a plurality of first conductive pillars 101 are sequentially formed on a surface of the separation layer 106 away from the carrier board 105. Specific structures of the lower redistribution layer 110 and the plurality of first conductive pillars 101 are referred to above, and will not be repeated here. Alternatively, the lower redistribution layer 110 can be formed by a photolithography process, and the first conductive pillar 101 can be formed by an electroplating method.

As shown in FIG. 2C, a patterned adhesive layer 120 is formed vertically on a surface of the lower redistribution layer 110 away from the separation layer 106, and a plurality of passive elements 130 and a plurality of active elements 140 are formed vertically on a surface of the patterned adhesive layer 120 away from the lower redistribution layer 110. The passive elements 130 and the active elements 140 are bonded to the lower redistribution layer 110 through the patterned adhesive layer 120. Specifically, the patterned adhesive layer 120 includes a plurality of adhesive units, and the plurality of adhesive units are arranged on the lower redistribution layer 110. Each passive element 130 and each active element 140 are arranged corresponding to one of the glue units. The passive elements 130 and the active elements 140 are bonded to the lower redistribution layer 110 through the patterned adhesive layer 120. Preferably, the patterned adhesive layer 120 can be a die attach film (DAF), and the patterned adhesive layer 120 can effectively enhance a stability of the passive element 130s and the active elements 140, thereby preventing the passive elements 130 and the active elements 140 from shifting or separating during subsequent processes. As shown in FIG. 2C, corresponding second conductive pillars 102 and third conductive pillars 103 are formed on surfaces of the passive element 130 and the active element 140 away from the lower redistribution layer 110. Specific structures of the passive element 130, the active element 140, the second conductive pillar 102, and the third conductive pillar 103 refer to the above, and will not be repeated here.

As shown in FIG. 2D, a first insulating layer 150 is formed vertically on surfaces of the lower redistribution layer 110, the passive element 130, and the active element 140 away from the lower redistribution layer 110. In this step, the first insulating layer 150 completely covers the surface of the lower redistribution layer 110 and all the surfaces of the passive element 130 and the active element 140 to encapsulate the passive element 130 and the active element 140. In some embodiments, the first insulating layer 150 may include a molding compound formed by a molding process. Alternatively, the first insulating layer 150 may be formed of an insulating material such as epoxy resin or other suitable resins.

As shown in FIG. 2E, a thinning process is applied to the first insulating layer 150 to reduce a thickness of the first insulating layer 150, and corresponding surfaces of the first conductive pillar 101, the second conductive pillar 102 on the passive element 130, and the third conductive pillar 103 on the active element 140 are exposed for electrical connection with subsequently formed elements. Alternatively, the thinning process can be achieved by using a grinder.

As shown in FIG. 2F, an upper redistribution layer 160 is formed vertically on a surface of the first insulating layer 150 away from the lower redistribution layer 110. The upper redistribution layer 160 includes a first surface 161 and a second surface 162 opposite to the first surface 161. A plurality of connection pads are formed on the first surface 161 and the second surface 162 of the upper redistribution layer 160. The upper redistribution layer 160 is electrically connected to the second conductive pillar 102 of the passive element 130 and the third conductive pillar 103 of the active element 140 through the corresponding connection pads. Furthermore, a plurality of wires are formed inside the upper redistribution layer 160, which are configured to connect to the corresponding connection pads. For specific structures of the upper redistribution layer 160, refer to the above, and will not be repeated here. In this embodiment, the upper redistribution layer 160 is also formed with connecting elements 107 protruding from the first surface 161, and these connecting elements 107 are arranged corresponding to the connection pads on the first surface 161. In some embodiments, the connecting elements 107 of the upper redistribution layer 160 can also be omitted to simplify the manufacturing process and improve production efficiency. Alternatively, the upper redistribution layer 160 can be formed by a photolithography process.

As shown in FIG. 2G, a plurality of die 170 are formed vertically on the first surface 161 of the upper redistribution layer 160. A plurality of bumps are formed on an active surface of the die 170. Material of the bump may be or include copper, gold, metal alloys, and the like. The die 170 adopts a flip chip bonding technology to bond the bumps to the upper redistribution layer 160 to realize the electrical connection between the die 170 and the upper redistribution layer 160. For specific structures of the die 170, refer to the above, and will not be repeated here. It should be noted that in the step of forming the die 170 on the upper redistribution layer 160, the die 170 is disposed to partially overlap the corresponding active element 140 and overlap the corresponding passive element 130. In this embodiment, an underfill layer 180 is also provided between the upper redistribution layer 160 and the die 170. Specifically, the underfill layer 180 can be formed in a gap between the active surface of the die 170 and the upper surface 161 of the upper redistribution layer 160, and laterally cover the corresponding connecting elements on the active surface and the upper surface 161 to enhance the bonding force between the die 170 and the upper redistribution layer 160 and enhance the reliability of the bonding. In some embodiments, the underfill layer 180 can be omitted to simplify the manufacturing process and improve the production efficiency.

As shown in FIG. 2H, a second insulating layer 190 is formed vertically on the die 170 and the first surface 161 of the upper redistribution layer 160. In this step, the second insulating layer 190 completely covers all surfaces of the die 170 and the first surface 161 of the upper redistribution layer 160 to encapsulate the die 170. In some embodiments, the second insulating layer 190 may include a molding compound formed by a molding process. Alternatively, the second insulating layer 190 may be formed of insulating materials such as epoxy resin or other suitable resins.

As shown in FIG. 2I, a thinning process is applied to the second insulating layer 190 to reduce a thickness of the second insulating layer 190 and expose a back surface 172 of the die 170. That is, in this embodiment, the second insulating layer 190 includes an opening, and the back surface 172 of the die 170 is exposed to an outside through the opening. With this design, a heat dissipation performance of the die 170 can be effectively improved. Alternatively, the thinning process can be achieved by using a grinder.

As shown in FIG. 2J, the carrier board 105 and the lower redistribution layer 110 are separated by the separation layer 106. The carrier board 105 can provide good support for the components formed above it to avoid a risk of structural deformation during the steps corresponding to FIG. 2A to FIG. 2I. In addition, separating the carrier board 105 in the step corresponding to FIG. 2J can effectively reduce an overall thickness of the structure.

As shown in FIG. 2K, a plurality of conductive terminals 104 are vertically formed on a surface of the lower redistribution layer 110 away from the passive element 130 and the active element 140. The conductive terminal 104 can be formed by using a bumping process, an electroplating process, or other suitable processes. In some embodiments, the conductive terminal 104 is a solder ball formed by a ball implantation process, thereby reducing the manufacturing cost and improving the manufacturing efficiency. It should be understood that, according to design requirements, the conductive terminal 104 may adopt other possible materials and shapes, and is not limited thereto. Alternatively, the bonding force between the conductive terminal 104 and the corresponding electrical pad of the lower redistribution layer 110 is enhanced by a welding process and a reflow process.

As shown in FIG. 2L, semi-finished products corresponding to FIG. 2K are disconnected along a separation line 108 to form multiple independent fan-out package structures 10. Alternatively, the disconnection of the semi-finished products can be realized by a cutting machine.

It should be noted that in the fan-out package structure 10 formed according to the steps corresponding to FIG. 2A to FIG. 2L, the die 170 may be a system-on-a-chip. The passive element 130 may be a bridge chip or a functional chip integrated with a bridge function. The active element 140 may be a memory chip or the like. In The passive element 130 is used to realize the signal transmission between the die 170 and the active element 140, which makes the arrangement of the die 170 and the active element 140 more flexible, and is not limited to that the two can only adopt a specific arrangement, such as a traditional packaging structure which arranges all active elements in parallel on the same layer. For example, in this embodiment, through the setting of the passive element 130, the die 170 and the active element 140 can be arrange at different levels, and when viewed from a top view, the die 170 and the active element 140 can be arranged to overlap each other. Specifically, the die 170 and the active element 140 are respectively arranged on opposite sides of the upper redistribution layer 160. In addition, an orthographic projection of the active element 140 on the upper redistribution layer 160 partially overlaps an orthographic projection of the die 170 on the upper redistribution layer 160. In some embodiments, the orthographic projection of the active element 140 on the upper redistribution layer 160 can also be designed to overlap the orthographic projection of the die 170 on the upper redistribution layer 160. That is, the orthographic projection of the active element 140 is within a range of the orthographic projection of the die 170. Therefore, in the fan-out package structure 10 of the present disclosure, under a condition of meeting a package width, a miniaturized and compactly designed multi-chip three-dimensional package is realized by the passive element 130. Thus, it provides more design flexibility and freedom for applications of the fan-out package structure 10 of the present disclosure in high-end products. On the other hand, in this embodiment, an orthographic projection of the passive element 130 on the upper redistribution layer 160 overlaps the orthographic projection of the die 170 on the upper redistribution layer 160. With the overlapping design of the passive element 130 and the die 170, a path for transmitting the main signal can be effectively shortened.

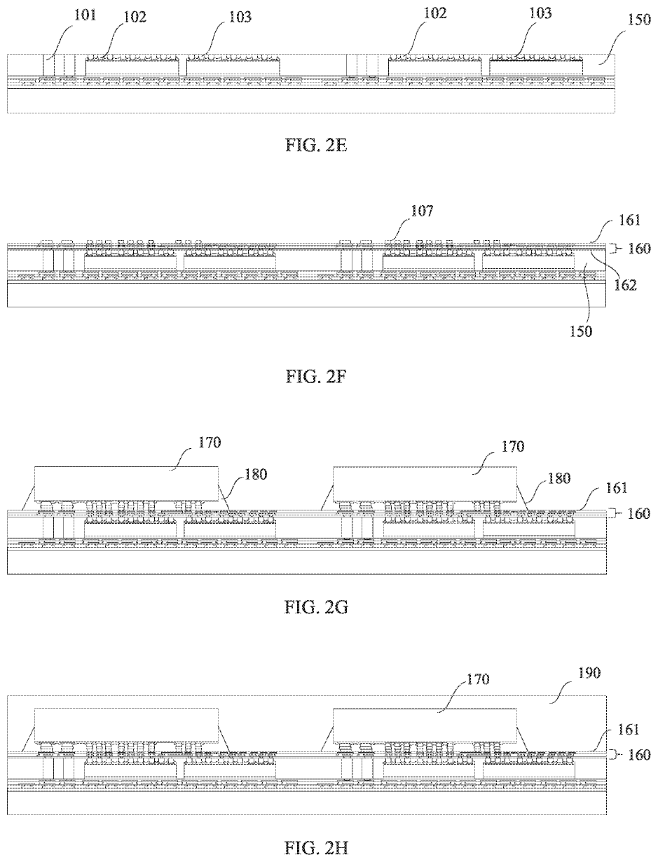

Referring to FIG. 3, which shows a schematic diagram of a fan-out package structure 20 of a second embodiment of the present disclosure. The fan-out package structure 20 of the second embodiment and the fan-out package structure 10 of the first embodiment have roughly the same structure. A difference between the two is that the underfill layer 180 of the first embodiment is omitted in the second embodiment to simplify the manufacturing process and improve the production efficiency. Furthermore, in the fan-out package structure 20 of the second embodiment, the second insulating layer 190 is formed in the gap between the active surface of the die 170 and the upper surface of the upper redistribution layer 160, and laterally covers connecting elements on the active surface of the die 170 and the corresponding upper surface 161. Therefore, the second insulating layer 190 can realize the encapsulation of the die 170 and the upper redistribution layer 160, and enhance the bonding force between the die 170 and the upper redistribution layer 160 and enhance the reliability of the bonding.

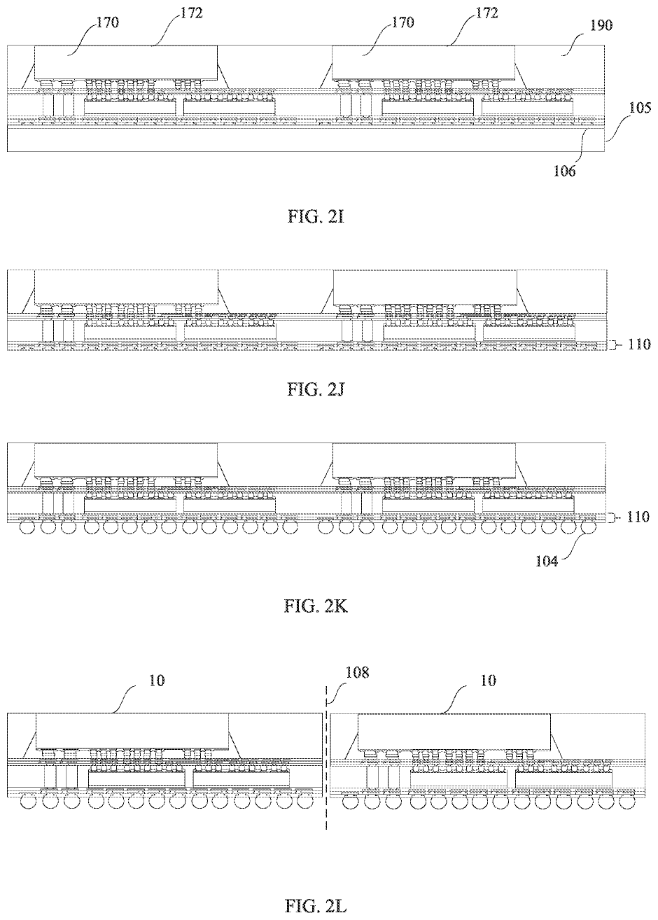

Refer to FIG. 4, which shows a schematic diagram of a fan-out package structure 30 of a third embodiment of the present disclosure. The fan-out package structure 30 of the third embodiment and the fan-out package structure 10 of the first embodiment have roughly the same structure. A difference between the two is that the second insulating layer 190 of the first embodiment is omitted in the third embodiment to simplify the manufacturing process and improve the production efficiency. Furthermore, in the fan-out package structure 30 of the third embodiment, the underfill layer 180 can realize the encapsulation of the die 170 and the upper redistribution layer 160, and enhance the bonding force between the die 170 and the upper redistribution layer 160 and enhance the reliability of the bonding. In this embodiment, the back surface of the die 170 can be exposed to the outside to ensure that the die 170 has good heat dissipation performance.

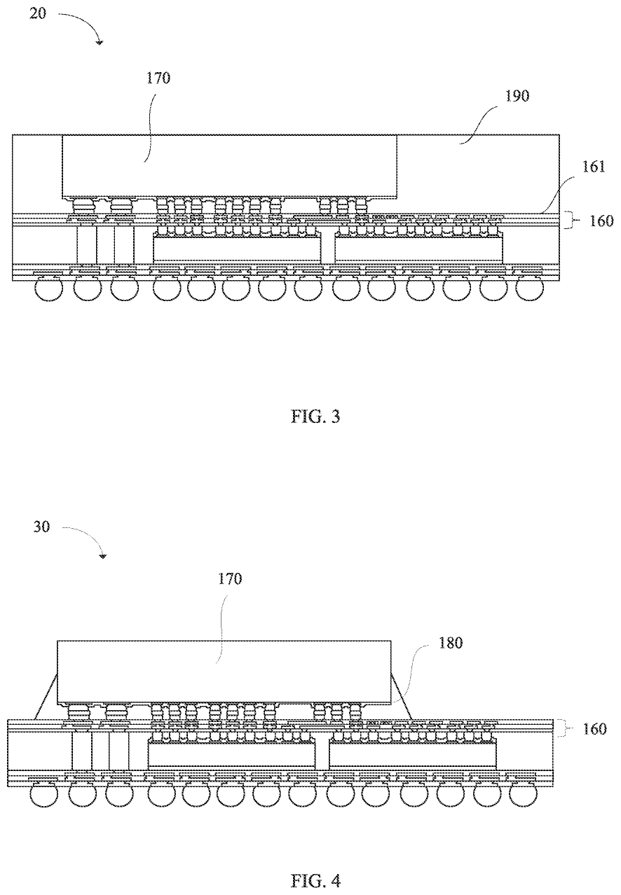

Refer to FIG. 5, which shows a schematic diagram of a fan-out package structure 40 of a fourth embodiment of the present disclosure. The fan-out package structure 40 of the fourth embodiment and the fan-out package structure 10 of the first embodiment have roughly the same structure. A difference between the two is that the second insulating layer 190 of the first embodiment is omitted in the fourth embodiment to simplify the manufacturing process and improve the production efficiency. In addition, the fan-out package structure 40 of the fourth embodiment also includes a protective cover 191. The protective cover 191 is preferably made of metal material. The protective cover 191 vertically covers the upper redistribution layer 160 and the die 170 to enhance the stability of the fan-out package structure 40 and avoid warpage and deformation.

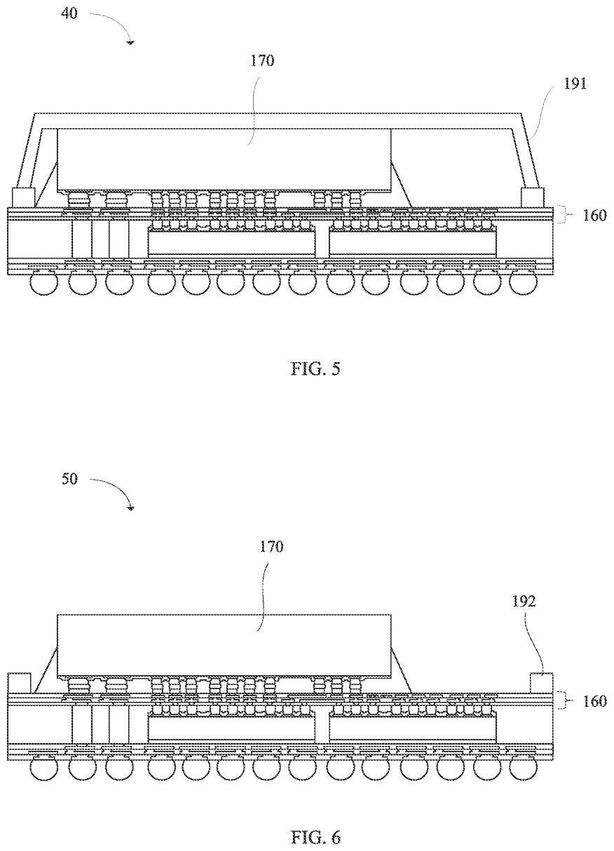

Refer to FIG. 6, which shows a schematic diagram of a fan-out package structure 50 of a fifth embodiment of the present disclosure. The structure of the fan-out package structure 50 of the fifth embodiment and the fan-out package structure 10 of the first embodiment are roughly the same. A difference between the two is that the second insulating layer 190 of the first embodiment is omitted in the fourth embodiment to simplify the manufacturing process and improve the production efficiency. In addition, the fan-out package structure 50 of the fifth embodiment also includes a protective ring 192. The protective ring 192 is preferably made of a metal material. The protective ring 192 is vertically arranged on the first surface of the upper redistribution layer 160 and surrounds the die 170. Alternatively, the protective ring 192 is arranged along an outer periphery of the first surface of the upper redistribution layer 160 to enhance the stability of the fan-out package structure 40 and avoid warpage and deformation. On the other hand, through the design of the protective ring 192, the back surface of the die 170 can be exposed to the outside, ensuring that the die 170 has good heat dissipation performance.

In summary, in the fan-out package structure and the manufacturing method thereof of the present disclosure, the passive element 130 can be a bridge chip or a functional chip integrated with a bridge function. The passive element 130 can realize the signal transmission between the die 170 and the active element 140, which makes the arrangement of the die 170 and the active element 140 more flexible, and is not limited to that the two can only adopt a specific arrangement, such as a traditional parallel arrangement. For example, by setting the passive element 130, the die 170 and the active element 140 can be arranged at different levels, and when viewed from a top view, the die 170 and the active element 140 can be arranged to overlap each other. Therefore, in the fan-out package structure of the present disclosure, by the passive element 130, a miniaturized and compactly designed multi-chip three-dimensional package is realized under the condition of meeting the package width. In other words, the electrical connection between multiple components can be realized without increasing the package size, thereby providing more design flexibility and freedom for the applications of the fan-out package structure of the present disclosure in high-end products.

The above are only specific implementations of the present disclosure, but the scope of protection of the present disclosure is not limited thereto. Any person with ordinary knowledge in the technical field can easily think of changes or replacements within the scope of the technology disclosed in the present disclosure, and they should be covered by the scope of protection of the present disclosure. Therefore, the protection scope of the present disclosure shall be subject to the protection scope of appended claims.

What is claimed is:

1. A fan-out package structure, comprising:
an upper redistribution layer comprising a first surface and a second surface opposite to the first surface;
a die disposed on the first surface of the upper redistribution layer and electrically connected to the upper redistribution layer;
a passive element disposed on the second surface of the upper redistribution layer and electrically connected to the upper redistribution layer; and
an active element disposed on the second surface of the upper redistribution layer and electrically connected to the upper redistribution layer, wherein the active element is laterally adjacent to the passive element, and the die is electrically connected to the active element and the passive element through the upper redistribution layer.

2. The fan-out package structure according to claim 1, wherein an orthographic projection of the active element on the upper redistribution layer partially overlaps with an orthographic projection of the die on the upper redistribution layer, and an orthographic projection of the passive element on the upper redistribution layer overlaps with the orthographic projection of the die on the upper redistribution layer.

3. The fan-out package structure according to claim 1, wherein the upper redistribution layer comprises:
a first connection pad formed on the first surface and configured to connect with the die;
a plurality of second connection pads formed on the second surface and configured to connect with the passive element;
a third connection pad formed on the second surface and configured to connect with the active element;
a first wire formed in the upper redistribution layer and configured to vertically connect the first connection pad and one of the plurality of second connection pads; and
a second wire formed in the upper redistribution layer and configured to laterally connect one of the second connection pads and the third connection pad.

4. The fan-out package structure according to claim 1, further comprising:
a first insulating layer disposed on the second surface of the upper redistribution layer and configured to encapsulate the passive element and the active element; and
a second insulating layer disposed on the die and the upper redistribution layer and configured to encapsulate the die, wherein the second insulating layer comprises an opening, and a surface of the die is exposed to an outside through the opening.

5. The fan-out package structure according to claim 1, further comprising:
a lower redistribution layer; and
a patterned adhesive layer disposed on the lower redistribution layer, wherein one surface of the passive element and one surface of the active element are adhered to the lower redistribution layer through the patterned adhesive layer, and one other surface of the passive element and one other surface of the active element are electrically connected to the upper redistribution layer.

6. The fan-out package structure according to claim 5, further comprising:
a first conductive pillar configured to connect the upper redistribution layer and the lower redistribution layer;
a second conductive pillar configured to connect the passive element and the upper redistribution layer; and
a third conductive pillar configured to connect the active element and the upper redistribution layer, wherein a pitch of the first conductive pillar is greater than or equal to a pitch of the third conductive pillar, and the pitch of the third conductive pillar is greater than or equal to a pitch of the second conductive pillar.

7. The fan-out package structure according to claim 1, further comprising a underfill layer disposed between the upper redistribution layer and the die.

8. The fan-out package structure according to claim 1, further comprising a protective ring or a protective cover disposed on the first surface of the upper redistribution layer and surrounding the die.

9. A manufacturing method of a fan-out package structure, comprising steps of:
providing a lower redistribution layer;
forming a passive element and an active element on the lower redistribution layer;
forming an upper redistribution layer on the passive element and the active element, wherein the passive element and the active element are electrically connected to the upper redistribution layer, and the passive element is laterally adjacent to the active element; and
forming a die on the upper redistribution layer, wherein the die is electrically connected to the passive element and the active element through the upper redistribution layer.

10. The manufacturing method of the fan-out package structure according to claim 9, wherein in the step of forming the die on the upper redistribution layer, the die is disposed to partially overlap with the active element and overlap with the passive element.
